(19) United States
(12) Patent Application Publication
(10) Pub. No.: US 2015/0221447 A1
(43) Pub. Date: Aug. 6, 2015

(54) COMPOSITION INCLUDING LIGHT-EMITTING COMPOUND EXHIBITING AFTERGLOW

(71) Applicants: SAMSUNG DISPLAY CO., LTD., Yongin-City, Gyeonggi-Do (KR); Tokyo Institute of Technology, Tokyo (JP)

(72) Inventors: Hideya Yuasa, Tokyo (JP); Hiroyuki Ohtani, Tokyo (JP); Atsushi Shimoyama, Tokyo (JP); Shinichi Kuno, Tokyo (JP)

(21) Appl. No.: 14/425,241

(22) PCT Filed: Aug. 23, 2013
(86) PCT No.: PCT/JP2013/072567

§ 371 Date: Mar. 2, 2015

(30) Foreign Application Priority Data
Aug. 28, 2012 (JP) 2012-187632

(51) Int. Cl. H01G 9/20; G01N 21/64; G06K 1/12; H01L 51/00

(52) U.S. Cl. CPC H01G 9/2059; H01L 51/005; H01L 51/0062; H01L 51/0072; H01L 51/0073; H01L 51/0067; H01L 51/0071; G01N 21/64; G06K 1/121; H01G 9/2027; H01L 51/441

(57) ABSTRACT

Provided is a light-emitting composition including a light-emitting compound that exhibits afterglow and represented by the following General Formula (1).

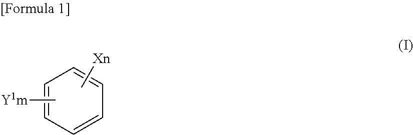

where Xn represents 1-4 carboxyl groups, dihydroxybornyl groups, or the like, and Y¹m represents 0-2 halogen atoms, methoxy groups, or phenyl groups.

### TECHNICAL FIELD

The present disclosure relates to a composition including a light-emitting compound exhibiting afterglow. The composition may be applied for the marker of a biomaterial, for the manufacture of a light-emitting printed matter, in an organic electroluminescent device (organic EL device), in an oxygen sensor, a solar cell, etc.

### BACKGROUND ART

A compound generating phosphorescence is used in an organic EL device, an oxygen sensor, etc.; however most of phosphorescent materials known until now are organic complexes or inorganic compounds. Until now, organic compounds generating phosphorescence at room temperature are rarely known. On the organic compounds generating phosphorescence at room temperature, there are a report (Non-patent Document 1) discloses that after being exposed to ultraviolet rays, tetraphenylmethane emits greenish blue light, a report (Patent Document 1) discloses that an organic EL device including a carbazole derivative emits red light, and a report (Patent Document 2) discloses that an aromatic compound introducing a tertiary amine or a secondary amine (fluorene, etc.) generates phosphorescence with the phosphorescent life of about 1 second in a matrix including a compound composed of molecules with a lump shape, in which a plurality of cyclo-rings are connected.

The emission life of a phosphorescent material is commonly 1 millisecond and less. Meanwhile, the emission life of a luminescent material(or light-accumulating luminous material) used in a luminous paint is commonly from several minutes to several hours. A phosphorescent material having an intermediate emission life between the two emission materials, that is, about several seconds is not known until now. In addition, in Patent Document 2, phosphorescence with the luminous life of about 1 second is detected, however, this phenomenon is detected in the above-described specific matrix, and phosphorescence with long life is not detected in conditions without the matrix.

### PRIOR ART DOCUMENTS

### Patent Documents

(Patent Document 1) JP2005-48004 A

(Patent Document 2) WO2009-069790 A

### Non-Patent Document

Daniel B. Clapp, Journal of the American Chemical Society, February 1939, Volume 61, issue 2, page 523

### DISCLOSURE OF THE INVENTION

### Technical Problem

The emission life of several seconds is significant in certification technique. A fluorescent material emits light only during irradiating lights, and lots of such materials are around. For example, almost all papers include a fluorescent paint to look white. Thus, the certification using the fluorescent paint has a low signal-to-noise (SN) ratio because surrounding lights are more intense than fluorescence. Meanwhile, a phosphorescent material emits light even after blocking lights, however such material is rare. Thus, surrounding lights seem to be removed, and an SN ratio is expected to be high. Meanwhile, since the emission life of the luminous material is too long, it is inappropriately used for coding.

The present disclosure is accomplished based on the above-described technical background, and provides a material having an emission life of about several seconds.

### Technical Solution

To solve the above tasks, the inventors of the present disclosure repeated close examination and found that a compound in which a carboxyl group, a dihydroxybornyl group, etc. was introduced in a benzene ring exhibited light-emitting properties, and the emission life thereof was about several seconds at room temperature and in conditions excluding other materials. Based on the foundation, the inventive concept was completed.

That is, the present disclosure provides the following (1) to (13).

(1) A light-emitting composition including a compound exhibiting afterglow and represented by the following General Formula (I).

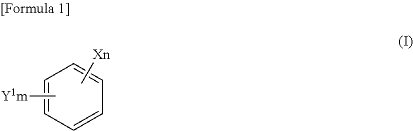

where Xn represents 1-4 carboxyl groups, carboxymethyl groups, dihydroxybornyl group, groups represented by —COOR¹ (where R¹ represents a hydrocarbon group), or groups represented by —B(OR²)(OR³) (where, R² and R³ are the same or different hydrocarbon groups, and R² and R³ may form a ring shape group with an oxygen atom and a boron atom), and Y¹m represents 0-2 halogen atoms, methoxy groups or phenyl groups.

(2) The light-emitting composition of the above (1), wherein Xn in General Formula (1) is 1-4 carboxyl groups, carboxymethyl groups, methoxycarbonyl groups, dihydroxybornyl groups, 1,3,2-dioxaborolan-2-yl groups or 1,3,2-benzodioxaborole-2-yl groups.

(3) The light-emitting composition of the above (1), wherein the compound represented by General Formula (1) is isophthalic acid, benzene-1,2,4,5-tetracarbonic acid, 2-(4-1,3,2-dioxaborolan-2-yl-phenyl)-1,3,2-dioxaborolan or 2-(4-chlorophenyl-1,3,2-dioxaborolan.

(4) The light-emitting composition according to any one of the above (1) to (3), wherein average emission life of the light-emitting compound is from about 0.07 to about 2.5 seconds.

(5) A method of marking a biomaterial including marking the biomaterial with the light-emitting composition described in any one of the above (1) to (4).

(6) A method of manufacturing a light-emitting printing matter, including printing an image on a base material using an ink including the light-emitting composition described in any one of the above (1) to (4).

(7) The method of manufacturing a light-emitting printing matter of the above (6), wherein the image is a bar code.

(8) An organic electroluminescent device including an anode, a cathode and an organic compound layer provided therebetween, wherein the organic compound layer includes the light-emitting composition described in any one of the above (1) to (4).

(9) A display using the organic electroluminescent device described in the above (8).

(10) An oxygen sensor including a support, an oxygen permeable layer and an emission layer provided therebetween, wherein the emission layer includes the light-emitting composition described in any one of the above (1) to (4).

(11) A method of measuring oxygen concentration including a process of contacting the oxygen sensor described in the above (10) with a sample, a process of irradiating lights to the oxygen sensor, a process of measuring emission life of phosphorescence generated from the emission layer by the irradiation of the lights, and a process of obtaining the oxygen concentration in the sample from the emission life.

(12) A solar cell including a metal oxide semiconductor electrode onto which a sensitizing dye is adsorbed and on a conductive support, a counter electrode thereof and an oxidation reduction electrolyte, wherein the sensitizing dye is the light-emitting composition described in any one of the above (1) to (4).

(13) A light-emitting method of the light-emitting composition described in any one of the above (1) to (4) by irradiating lights to the light-emitting composition.

In addition, the present disclosure provides a compound represented by the following General Formula (II) or (III) besides the compound represented by the above General Formula (I).

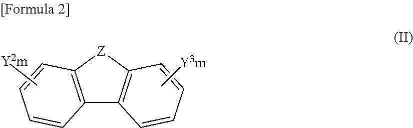

where Y²m and Y³m represent the same or different 0-2 halogen atoms, methoxy groups or phenyl groups, and Z represents a nitrogen atom or an oxygen atom.

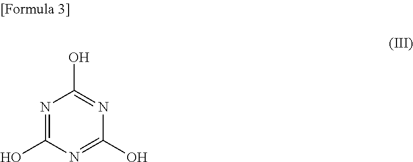

### Advantageous Effects

Since the compound represented by General Formula) (hereinafter will be referred to as “a compound of the inventive concept”) has the emission life of about several seconds, the emitted light may be detected by blocking excitation light and excluding noise fluorescence. In addition, since the emission life thereof is longer than a commonly known phosphorescent material, a scanner with high definition, etc. is not necessary, and the detection may be conducted using a cheap apparatus.

### BRIEF DESCRIPTION OF THE DRAWINGS

FIG. 1 illustrates the structures of compounds (Compounds 1-21) used in embodiments where numbers represent the numbers of the compounds;

FIG. 2 illustrates the structures of compounds (Compounds 22-37) used in embodiments where numbers represent the numbers of the compounds;

FIG. 3 illustrates the emission spectrum and the attenuation curve of Compound 7 (upper) and the emission spectrum and the attenuation curve of Compound 28 (lower); and

FIG. 4 illustrates the emission states of Compound 30 from the initiation of the irradiation of UV to after about 8 seconds (upper) and the emission states of Compound 2 from the initiation of the irradiation of UV to after about 8 seconds (lower).

### MODE FOR CARRYING OUT THE INVENTION

Hereinafter, the inventive concept will be described in detail.

In the present disclosure, the term “halogen atom” means, for example, a fluorine atom, a chlorine atom, a bromine atom, an iodine atom, etc.

In the present disclosure, the term “hydrocarbon group” means, for example, a linear or branched alkyl group, a cyclic alkyl group, a linear or branched alkenyl group, an aryl group, etc. Here, the term “linear or branched alkyl group” means, for example, a methyl group, an ethyl group, a propyl group, an isopropyl group, a butyl group, an isobutyl group, an s-butyl group, a t-butyl group, etc., the term “cyclic alkyl group” means, for example, a cyclopropyl group, a cyclobutyl group, a cyclopentyl group, a cyclohexyl group, etc., the term “linear or branched alkenyl group” means, for example, a vinyl group, an allyl group, etc., and the term “aryl group” means, for example, a phenyl group, etc.

In the present disclosure, the term “cyclic shape group which may be formed by R² and R³ with an oxygen atom and a boron atom” means, for example, 1,3,2-dioxaborolan-2-yl group, 2-benzodioxaborole-2-yl group, etc.

In General Formula (1), Xn may appropriately be a carboxyl group, a carboxymethyl group, a methoxycarbonyl group, a dihydroxybornyl group, a 1,3,2-dioxaborolan-2-yl group or a 1,3,2-benzodioxaborole-2-yl group and may more appropriately be the carboxyl group or the 1,3,2-dioxaborolan-2-yl group. In addition, in the case that Xn is the dihydroxybornyl group or an ester group thereof (1,3,2-dioxaborolan-2-yl group), the emission life thereof tends to be increased. Thus, to attain the property, the groups may preferably be used.

In General Formula (1), Y¹m may preferably be a chlorine atom. In the case that Y¹m is the chlorine atom, emission intensity tends to be increased. Thus, to attain the property, the chlorine atom may preferably be used.

In General Formula (1), the appropriate number of Xn is two.

In General Formula (1), the appropriate number of Y¹m is one.

In addition, in the case that the numbers of Xn, Y¹m, Y²m and Y³m are two and above, the groups represented thereby may be the same or different.

In General Formula (1), the appropriate position of Xn is position 1 and position 3 or 4.

In General Formula (1), the appropriate position of Y¹m is position 4.

In addition, the positions of Xn and Y¹m are positions in the following General Formula (Ia).

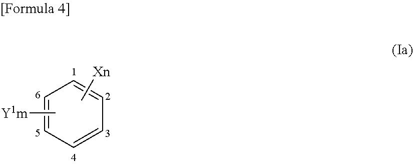

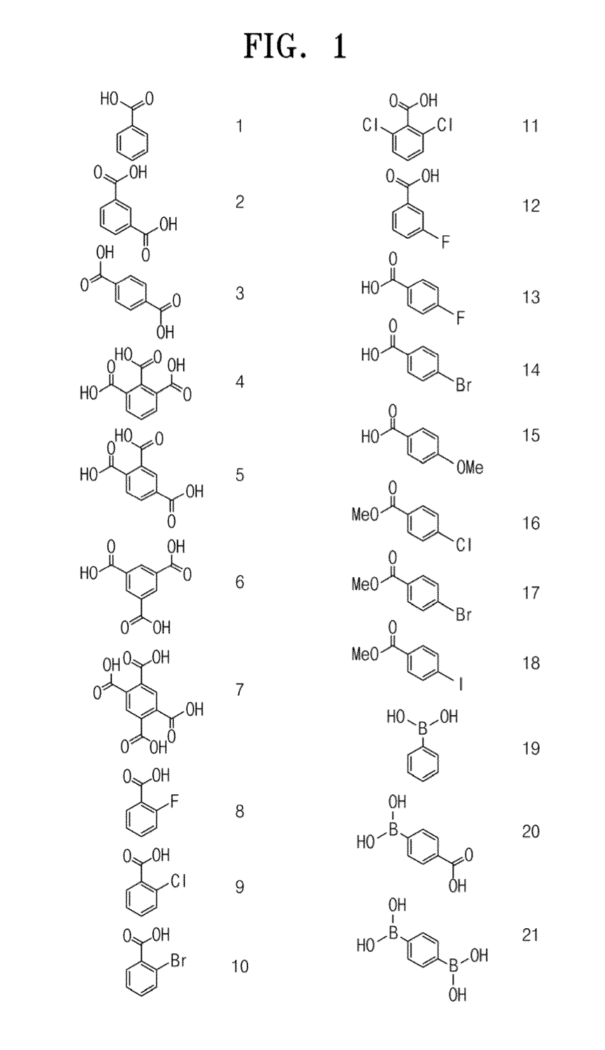

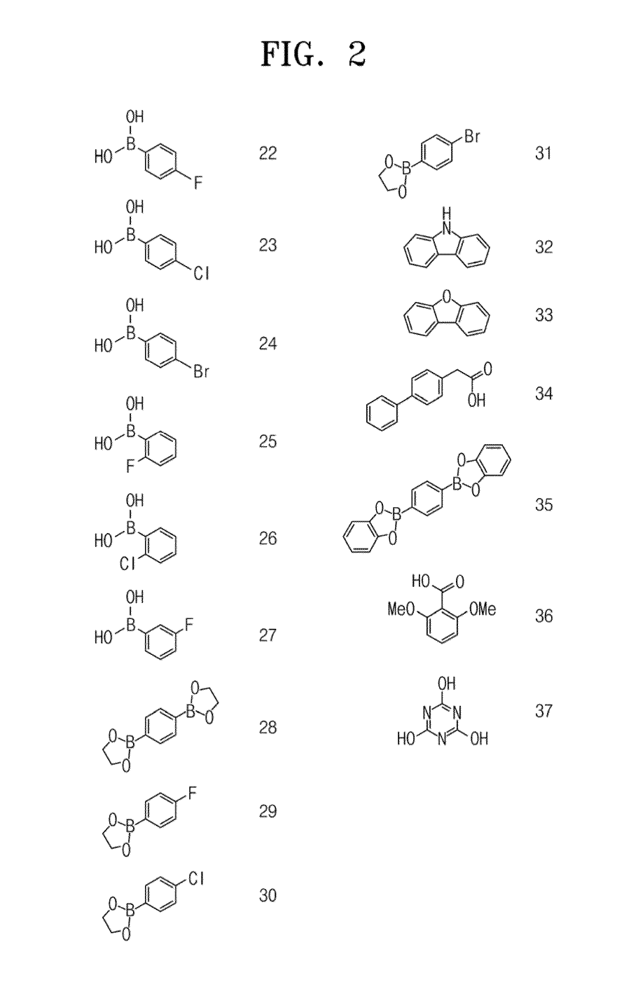

Particular examples of the compounds of the inventive concept may include Compounds 1 to 37 shown in FIGS. 1 and 2. Among the compounds, particularly preferable compounds may include isophthalic acid (Compound 2), benzene-1,2,4,5-tetracarbonic acid (Compound 7), 2-(4-1,3,2-dioxaborolan-2-yl-phenyl)-1,3,2-dioxaborolan (Compound 28) or 2-(4-chlorophenyl)-1,3,2-dioxaborolan (Compound 30).

The compounds of the inventive concept are known compounds, and the compounds may be obtained on the market or synthesized by a known method.

The compound of the inventive concept is a compound capable of emitting light after blocking excitation light, that is, compound generating phosphorescence (light-emitting compound with afterglow). The average emission life of the compound of the inventive concept is dependent on the kinds thereof, however is commonly from about 0.7 to about 2.5 seconds and is appropriately from about 1.0 to about 2.0 seconds. Here, the definition of the so-called “average emission life” is described in the embodiments of the present disclosure. In addition, in the case that a plurality of peaks are in emission wavelength, a weighted average is obtained in consideration of emission intensity measured for the wavelength of each peak, and a weighted average value is regarded as the average emission life. The range of excite wavelength for the light emission of the compound of the inventive concept is different for each compound, however is commonly from about 250 nm to about 400 nm, and is appropriately from about 280 nm to about 320 nm. In addition, the emission wavelength of the compound of the inventive concept is different for each compound, however is commonly from about 440 nm to about 550 nm, and is appropriately from about 490 nm to about 510 nm.

The temperature at the light emission is not specifically limited, however is commonly from about −196° C. to about 30° C., and is appropriately from about 10° C. to about 25° C.

The light-emitting composition including the compound of the inventive concept may be used in diverse uses requiring light-emitting properties. For example, the following uses of (1) to (5) may be illustrated.

(1) Marking of Biomaterial

For the marking of a biomaterial, a fluorescent material with a low molecular weight (and non-protein) (for example, fluorescein isothiocyanate rhodamine, etc.) is commonly used. Since the fluorescent material does not emit light immediately after blocking excitation light, the image of the marked biomaterial is necessary to be observed under the irradiation of the excitation light. However, since lots of fluorescent materials are present in the biomaterial, and the fluorescent materials are present as background lights under the irradiation of the excitation light, the SN ratio of an obtainable image may be decreased.

In the case that the biomaterial is marked by the compound of the inventive concept, light emission may be maintained after the blocking of the excitation light, and the biomaterial may be observed after the blocking of the excitation light. Since a light-emitting material with afterglow is rarely present in the biomaterial, the SN ratio after the blocking of the excitation light may be increased.

The marking of the biomaterial with the compound of the inventive concept may be performed according to a marking method of a fluorescent material commonly used. For example, in the case of marking a protein, fluorescein, etc. may be combined with the protein using a linker such as isothiocyanate. The compound of the inventive concept may be also combined with the protein using such a common linker. In addition, some compounds of the inventive concept include a carboxyl group, and the compounds may mark the protein via the combination with the amino group of the protein with the carboxyl group.

The biomaterial which is a subject of marking is not specifically limited and may include proteins, nucleic acids, saccharides, carbohydrates, etc.

(2) Manufacture of Light-Emitting Printing Matter

The printing of an image using an ink including a fluorescent material is commonly conducted. Since the fluorescent material does not emit light immediately after blocking excitation light, the image printed emits light only under the irradiation of the excitation light. However, since lots of fluorescent materials are included in a base material (paper, etc.) for printing images, and the fluorescent materials are present as background lights, the SN ratio of the image printed may be decreased.

In addition, the printing of a bar code using an ink including a phosphorescent material is commonly conducted (for example, U.S. Pat. No. 5,861,618, etc.). Since the bar code thus printed emits light after blocking excitation light, the SN ratio thereof may be increased. However, the emission life of the phosphorescent material is 1 millisecond and less, an expensive bar code detector for recognizing the light emission for such a short time period has no option but to use.

Since the compound of the inventive concept continuously emits light for about several seconds after the blocking of excitation light, an image with a high SN ratio may be obtained, and the price of an apparatus for detecting the image may be decreased.

The ink including the compound of the inventive concept may be prepared by the same method as a commonly used ink including a fluorescent material. The image to be printed is not specifically limited, however may include characters, symbols, patterns, bar codes, person images or landscapes used as embedded figures in a paper money. The base material for printing is not specifically limited, however may include paper, texture, wood, etc.

On one base material, an image of an ink including a common fluorescent material may be printed other than an image of an ink including the compound of the inventive concept. In this case, two kinds of information may be recorded on the base material, and the prevention of the forgery of bank notes may be favorable.

(3) Organic EL Device, and Display and Illumination Using the Same

Organic EL devices using a fluorescent material or a phosphorescent material are disclosed (for example, Japanese Laid-open Patent Publication No. 2005-48004, Japanese Laid-open Patent Publication No. 2009-30038 and Japanese Laid-open Patent Publication No. 2009-209142). The light-emitting composition of the inventive concept may be used instead of the common fluorescent material used in the organic EL device. As described above, the light-emitting composition of the inventive concept emits phosphorescence. For fluorescence, only a singlet excited state contributes to light emission. In contrast, for phosphorescence, a triplet excited state also contributes to light emission. Thus, the emission efficiency of the phosphorescence is higher than that of the fluorescence. Thus, an organic EL device using the light-emitting composition of the inventive concept (organic EL device of the inventive concept) has higher emission efficiency than the organic EL device using a fluorescent material.

The organic EL device of the inventive concept includes an anode, a cathode and an organic compound layer provided therebetween. The organic compound layer may include the light-emitting composition of the inventive concept. The organic EL device of the inventive concept may be the same as a common organic EL device except for using the light-emitting composition of the inventive concept. Particular explanation is as follows.

The organic EL device of the inventive concept includes the anode, the cathode and the organic compound layer as described above and may further include a substrate for laminating the anode thereon, a hole transport layer provided between the anode and the organic compound layer and an electron transport layer provided between the cathode and the organic compound layer.

As the substrate, a transparent insulating substrate may be used with respect to the emission wavelength of the light-emitting composition of the inventive concept. Particularly, glass, polyethyleneterephthalate, polycarbonate, etc. may be used.

The organic compound layer may be formed by dissolving the light-emitting composition of the inventive concept in an appropriate solvent to prepare a solution and forming a layer using the solution by an inkjet method, a spin coating method, a dip coating method, a printing method, etc. The organic compound layer may be formed by mixing a polymer material (for example, polymethylmethacrylate, polycarbonate, polyester, polysulfone and polyphenyleneoxide) as a binder. Alternatively, the organic compound layer including the light-emitting composition of the inventive concept may be formed by an evaporation method for evaporating or sublimating an organic compound.

The hole transport layer may be formed using a known hole transport material such as TPD, α-NPD, m-MTDATA, etc.

The electron transport layer may be formed using a known electron transport material such as a metal complex of a quinolinol derivative (for example, Alq₃), etc.

The anode may be formed using a known anode material such as indium tin oxide (ITO), tin oxide, zinc oxide, polythiophene, polypyrrole, polyaniline, etc.

The cathode may be formed using a known cathode material including an alkali metal such as Li, Na, K, Cs, etc., an alkaline earth metal such as Mg, Ca, Ba, etc., aluminum, an MgAg alloy, an AlLi alloy, an AlCa alloy, etc.

The organic EL device of the inventive concept may be used in a display (organic EL display), an illumination, etc.

(4) Oxygen Sensor and Measuring Method of Oxygen Concentration

The emission life of a phosphorescent material is decreased depending on the concentration of oxygen, and an oxygen sensor or a measuring method of oxygen concentration using the property has been known (Japanese Laid-open Patent Publication No. Sho 62-503191, Japanese Laid-open Patent Publication No. Pyeong 11-3792, Japanese Laid-open Patent Publication No. 2007-232716 and Japanese Laid-open Patent Publication No. 2013-53901). The light-emitting composition of the inventive concept may be used instead of the phosphorescent material used in the oxygen sensor or the measuring method of oxygen concentration. Since the light-emitting composition of the inventive concept has longer emission life than known phosphorescent materials, an apparatus with high precision is not necessary for measuring the emission life, and a cheap measuring apparatus may be used.

The oxygen sensor using the light-emitting composition of the inventive concept (oxygen sensor of the inventive concept) may include a support, an oxygen permeable layer and an emission layer provided therebetween. The emission layer may include the light-emitting composition of the inventive concept. In addition, the measuring method of oxygen concentration using the light-emitting composition of the inventive concept (measuring method of oxygen concentration of the inventive concept) may include a process of contacting the oxygen sensor of the inventive concept with a sample, a process of irradiating light to the oxygen sensor of the inventive concept, a process of measuring emission life of phosphorescence generated from the emission layer by the irradiation of lights, and a process of obtaining oxygen concentration in the sample from the emission life. The oxygen sensor and the measuring method of oxygen concentration of the inventive concept may be the same as a common oxygen sensor and a common measuring method of oxygen concentration except for using the light-emitting composition of the inventive concept. Particular explanation is as follows.

As the material of the support, a transparent material which may pass excitation light is preferable, and plastic, glass, quartz, etc., may be included. The shape of the support is not specifically limited, however a plate shape, a rod shape, a sheet shape, a spherical shape, etc. may be included.

The oxygen permeable layer is not specifically limited only if capable of passing oxygen and has a certain mechanical strength. As a preferable material forming the oxygen permeable layer, silicon, etc. may be used.

The emission layer may be formed by forming a thin film using a polymer obtained by dispersing the light-emitting composition of the inventive concept. The polymer used is not specifically limited, however a transparent material is preferable, and polystyrene, polyacrylate, polysiloxane, etc. may be used.

For the contact of the oxygen sensor of the inventive concept with the sample, oxygen in the sample is required to make contact with the light-emitting composition of the inventive concept. Thus, the oxygen permeable layer and the sample are required to make contact.

The irradiation of lights and the measurement of emission life may be conducted using a commercially available light-emission measuring apparatus.

As described above, since the emission life is decreased according to the concentration of oxygen, the emission life of a sample of which oxygen concentration is known is measured in advance, and the oxygen concentration of the sample for measuring is obtained from the measured values.

(5) Solar Cell

As the sensitizing dye of a dye-sensitized solar cell, a phosphorescent material is used (Japanese Laid-open Patent Publication No. 2005-255992). The light-emitting composition of the inventive concept may be used instead of the phosphorescent material used in the solar cell.

The solar cell using the light-emitting composition of the inventive concept (solar cell of the inventive concept) includes a metal oxide semiconductor electrode onto which a sensitizing dye is adsorbed, a counter electrode the metal oxide semiconductor electrode and an oxidation reduction electrolyte. the metal oxide semiconductor electrode disposed on a conductive support. The sensitizing dye may include the light-emitting composition of the inventive concept. The solar cell of the inventive concept may be the same as a common dye-sensitized solar cell except for using the light-emitting composition of the inventive concept. Particular explanation is as follows.

As a material constituting the metal oxide semiconductor electrode, for example, titanium oxide, niobium oxide, zinc oxide, tin oxide, tungsten oxide, indium oxide, etc. may be used, and the titanium oxide is preferable among them. Even though the method of forming the metal oxide semiconductor electrode is not specifically limited, the metal oxide semiconductor electrode may be formed by, for example, preparing particles of a metal oxide, suspending the particles in an appropriate solvent and coating the appropriate solvent on a conductive support, removing the solvent and heating.

The method of adsorbing the light-emitting composition of the inventive concept onto the metal oxide semiconductor electrode is not specifically limited, however, for example, the metal oxide semiconductor electrode may be immersed in a solution including the light-emitting composition of the inventive concept.

As the oxidation reduction electrolyte, an I⁻/I³⁻-based, Br²⁻/Br³⁻-based, Co²⁺/Co³⁺-based, Fe²⁺/Fe³⁺-based electrolyte may be used, and as the solvent, acetonitrile, propylenecarbonate, etc. may be used.

As the counter electrode, a conductive material may be used without specific limitation. For example, an electrode obtained by depositing platinum on the surface of a conductive support or an electrode obtained by attaching conductive carbon on the surface of a conductive support may be used.

### EXAMPLES

Hereinafter, the inventive concept will be explained in more detail referring to embodiments, however the inventive concept is not limited thereto.

(1) Experimental Methods

(1-1) Measuring Time-Resolved Emission Spectrum

Time-resolved emission spectra of 37 kinds of compounds shown in FIGS. 1 and 2 were measured. For the measurement, a FP-8500 apparatus for measuring time-resolved light emission of Japan Spectroscopy Co., Ltd. and a cell for a powder with a diameter of about 5 mm were used at room temperature of about 23° C. The followings are detailed settings.

| Measuring mode | phosphorescence | |
|---|---|---|
| Excite band width | 5 | nm |
| Fluorescent band width | 5 | nm |
| Sensitivity | very low | |
| Period | 100 | ms |
| Delay time | 50 | ms |
| Integration time | 25 | ms |
| Response | 0.2 | s |

Emission life was obtained by measuring time change in the same apparatus.

| | | |
|---|---|---|
| Excite band width | 20 | nm |
| Fluorescent band width | 20 | nm |
| Response | 10 | ms |

The values of A and τ were obtained by designating the axis of ordinate of an attenuation curve (axis of abscissas: time, axis of ordinate: emission intensity) by log and fitting by the following equation in a straight-line section. The value of τ is time required for the attenuation of the emission intensity to 37%.

y=A*exp(−x/τ)

In the case that the log plot of the attenuation curve made approximately a curve, the fitting was performed by the following equation.

y=Aₙ*exp(−x/τₙ)

In this case, since Aₙ is a distribution rate of a τₙ component, average emission life (τ) was obtained by the following equation.

τ=Aₙ*τₙ

(1-2) Measuring Fluorescent Quantum Yield

Fluorescent quantum yield was measured using a spectroscopic fluorescent photometer FP-8500 (Japan Spectroscopy Co., Ltd.) and an ILF-type integrating sphere unit with 100 mmφ (Japan Spectroscopy Co., Ltd.).

The measuring of the fluorescent spectrum of the sample was as follows. A sample of a solid phase was put in a powder cell with about 3 mm (Japan Spectroscopy Co., Ltd.), and the powder cell was inserted in the integrating sphere unit connected to the above-described photometer. Then, excitation light having excited wavelength was irradiated to the sample so that the fluorescent intensity of the sample became the highest. In addition, as measuring parameters, a measuring mode was set to fluorescence, an excited band width and a fluorescent band width were set to about 10 nm, and response was set to about 0.5 sec.

The fluorescent quantum yield means inner quantum efficiency (ε in; conversion efficiency of photons absorbed by the sample into fluorescence) obtained by dividing the photon number of fluorescence emitted from the sample (Nem) by the quantum number of excitation light absorbed by the sample (Nabs). In addition, indirect excitation correction was performed in consideration of the effect of indirect excitation by which excitation light scattered in the sample might diffuse in the integral sphere and re-excite the sample. That is, a calculation formula for obtaining the inner quantum efficiency (ε in) may be represented as the following.

$$\begin{matrix}ɛ in = \frac{Nem}{Nabs} \\ = \frac{E 1 - \frac{L 2}{L 3} E 2}{L 1 - \frac{L 1}{L 3} L 2}\end{matrix} \qquad [ Mathematical Formula 1 ]$$

Here, L1 represents a wrapping area with the spectrum of excitation light, L2 represents a wrapping area with the spectrum of scattered excitation light by the sample, L3 represents a wrapping area with the spectrum of excitation light indirectly irradiated to the sample and scattered, E1 represents a wrapping area with the fluorescent spectrum of the sample, and E2 represents a wrapping area with the fluorescent spectrum of the sample to which the excitation light is indirectly irradiated. Practically, a quantum yield calculation program (Japan Spectroscopy Co., Ltd.) was used to compute the fluorescent quantum yield.

(2) Experimental Results

The maximum excited wavelength, the maximum emission wavelength, the average emission life and the fluorescent quantum yield of each compound are illustrated in Table 1. In Table 1, in the column of recrystallization, the description of “reagent” or “synthesized product” means that a commercially available reagent or a synthesized product was used as a measuring subject as it is, and the description of “water”, “methanol” or “ethanol” means that a reagent, etc. is dissolved in the illustrated solvent and recrystallized to obtain a measuring subject. In Table 1, “n.d.” means no detection.

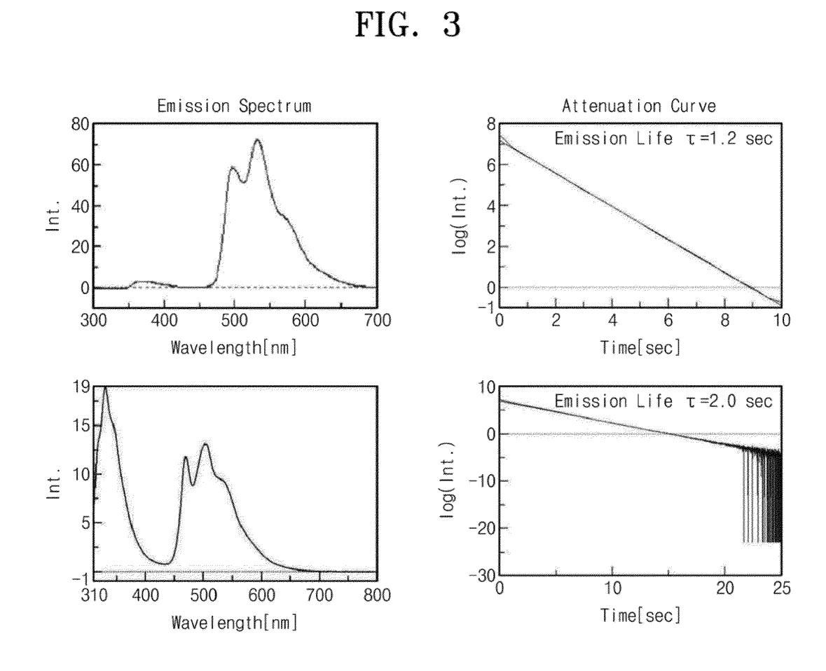

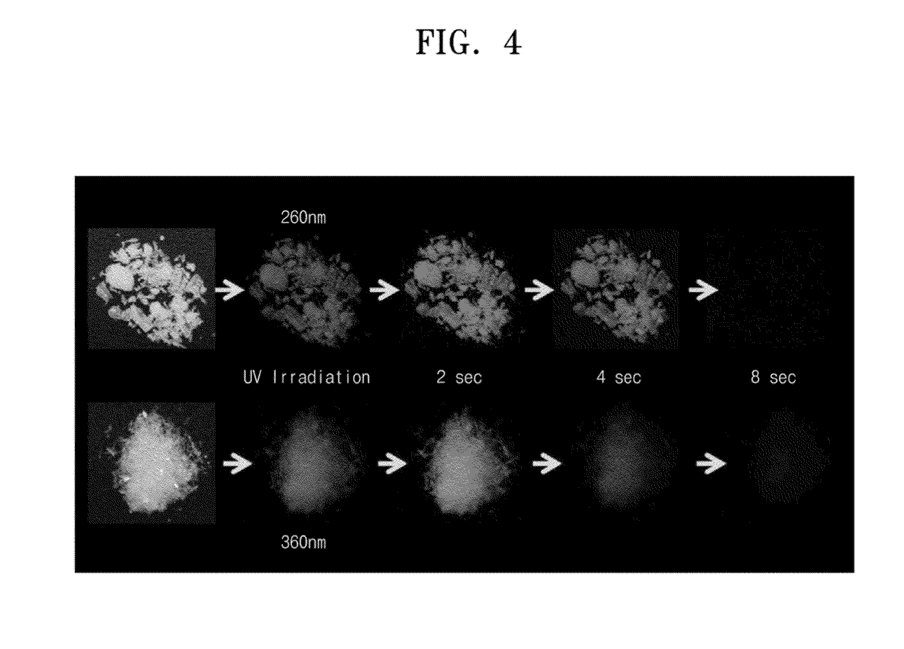

In addition, the emission spectra and the attenuation curves of Compound 7 and Compound 28 are illustrated in FIG. 3, and the emission states of Compound 30 and Compound 2 from the initiation of the irradiation of UV to after about 8 seconds are illustrated in FIG. 4.

TABLE 1

| | | | | | | | | Weighted | | |
|---|---|---|---|---|---|---|---|---|---|---|
| | Pex | Pem | Average life | | | | | average | | Fluorescent quantum yield (%) |
| No. | (nm) | (nm) | τ1(s) | τ2(s) | τ3(s) | τ4(s) | τ5(s) | Average life (s) | Recrystallization | (fluorescent excitation wavelength, nm) |
| 1 | 304 | 498 | 1.5 | 0.67 | 0.31 | 0.11 | — | 0.33 | reagent | 14 (260) |
| 2 | 309 | 500 | 2.5 | 1.5 | 0.33 | 0.098 | — | 0.81 | methanol | 28 (313) |
| 3 | 335 | 516 | 0.98 | 0.59 | 0.19 | 0.048 | 0.011 | 0.35 | ethanol | 18 (319) |
| 4 | 319 | 500 | 1.1 | 0.56 | 0.21 | 0.047 | — | 0.37 | methanol | 2.5 (295) |
| 5 | 320 | 536 | 1.1 | 0.66 | 0.19 | 0.067 | 0.016 | 0.59 | reagent | 2.2 (303) |
| 6 | 330 | 525 | 0.94 | 0.53 | 0.23 | 0.048 | — | 0.43 | reagent | 1.4 (300) |
| 7 | 354 | 533 | 1.2 | 0.69 | — | — | — | 1.1 | water | 9.2 (338) |
| 8 | 316 | 510 | 1.4 | 0.70 | 0.33 | 0.11 | — | 0.38 | reagent | 3.1 (303) |
| 9 | 322 | 512 | 0.33 | 0.18 | 0.084 | 0.020 | — | 0.15 | reagent | 12 (327) |
| 10 | 352 | 518 | 0.68 | 0.26 | 0.093 | 0.028 | 0.0091 | 0.074 | reagent | 6.7 (329) |
| 11 | 279 | 496 | 1.6 | 0.36 | 0.14 | 0.074 | 0.032 | 0.075 | reagent | 0.95 (260) |
| 12 | 322 | 540 | 1.0 | — | — | — | — | 1.0 | reagent | n.d. |
| 13 | 300 | 495 | 0.69 | 0.32 | 0.12 | 0.024 | — | 0.25 | reagent | n.d. |
| 14 | 333 | 512 | 0.39 | 0.16 | 0.075 | 0.016 | — | 0.14 | reagent | 13 (218) |
| 15 | 318 | 526 | 3.1 | 1.2 | 0.52 | 0.17 | — | 0.58 | reagent | n.d. |
| 16 | 295 | 508 | 0.92 | 0.49 | 0.19 | 0.062 | 0.020 | 0.11 | reagent | 13 (302) |
| 17 | 297 | 520 | 0.63 | 0.29 | 0.074 | 0.017 | — | 0.33 | reagent | 6.3 (292) |
| 18 | 324 | 523 | 0.14 | 0.063 | 0.030 | — | — | 0.046 | reagent | 0.86 (320) |
| 19 | 289 | 479 | 1.7 | 1.1 | — | — | — | 1.2 | water | 29(250) |
| 20 | 267 | 520 | 0.68 | 0.45 | 0.15 | — | — | 0.47 | reagent | n.d. |
| 21 | 257 | 495 | 1.5 | 0.91 | 0.31 | 0.089 | — | 0.87 | water | 75 (249) |
| 22 | 283 | 497 | 3.0 | 1.8 | — | — | — | 2.1 | reagent | 34 (325) |
| 23 | 282 | 484 | 1.8 | 0.71 | 0.28 | 0.13 | — | 0.20 | reagent | 9.0 (302) |
| 24 | 302 | 513 | 1.3 | 0.27 | 0.13 | 0.045 | — | 0.095 | reagent | 2.1 (314) |
| 25 | 307 | 480 | 3.0 | 1.8 | — | — | — | 2.2 | reagent | n.d. |
| 26 | 265 | 500 | 1.2 | 0.53 | 0.16 | 0.047 | 0.016 | 0.17 | reagent | n.d. |
| 27 | 300 | 527 | 2.3 | 0.75 | 0.32 | 0.11 | — | 0.35 | reagent | n.d. |
| 28 | 300 | 500 | 2.2 | 1.4 | 0.39 | 0.075 | — | 1.9 | synthesized product | 77 (252) |
| 29 | 289 | 489 | 3.0 | 1.9 | — | — | — | 2.2 | synthesized product | 53 (313) |
| 30 | 290 | 499 | 1.4 | 0.31 | 0.20 | — | — | 0.25 | synthesized product | 10 (302) |
| 31 | 304 | 501 | 0.85 | 0.23 | 0.14 | — | — | 0.16 | synthesized product | 7.3 (309) |
| 32 | 376 | 547 | 1.1 | — | — | — | — | 1.1 | reagent | n.d. |
| 33 | 323 | 530 | 1.1 | 0.42 | 0.094 | 0.031 | — | 0.088 | reagent | n.d. |
| 34 | 298 | 535 | 0.47 | 0.31 | 0.054 | — | — | 0.43 | reagent | 23 (328) |
| 35 | 343 | 533 | 1.4 | 0.78 | 0.25 | 0.058 | — | 1.2 | synthesized product | n.d. |
| 36 | 335 | 520 | 2.0 | 0.90 | 0.34 | 0.11 | — | 0.55 | reagent | 6.1 (312) |
| 37 | 310 | 440 | 2.2 | 1.1 | 0.43 | 0.12 | 0.032 | 0.66 | reagent | n.d. |

### INDUSTRIAL APPLICABILITY

The inventive concept may be used in various industrial fields requiring a light-emitting material.

This application includes the contents disclosed in the specification and/or drawings of Japanese Patent Application No. 2012-187632, which is the priority of the present disclosure. In addition, all publications, patents and patent applications cited in this disclosure are hereby incorporated by reference.

1. A light-emitting composition, comprising a compound exhibiting afterglow, the compound being represented by the following Formula (1): 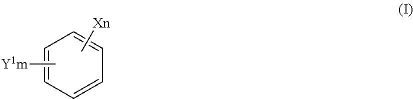
wherein, in Formula 1,
X is a carboxyl group, a carboxymethyl group, a dihydroxybornyl group, a group represented by —COOR¹, in which R¹ is a hydrocarbon group, or a group represented by —B(OR²)(OR³), in which R² and R³ are each independently a hydrocarbon group, and R² and R³ are separate from each other or form a ring along with an oxygen atom and a boron atom, wherein n is 1, 2, 3, or 4, and
Y¹ is a halogen atom, a methoxy group, or a phenyl group, wherein m is 0, 1, or 2.

2. The light-emitting composition of claim 1, wherein X in Formula (1) is a carboxyl group, a carboxymethyl group, a methoxycarbonyl group, a dihydroxybornyl group, a 1,3,2-dioxaborolan-2-yl group, or a 1,3,2-benzodioxaborole-2-yl group.

3. The light-emitting composition of claim 1, wherein the compound represented by Formula (1) is isophthalic acid, benzene-1,2,4,5-tetracarbonic acid, 2-(4-1,3,2-dioxaborolan-2-yl-phenyl)-1,3,2-dioxaborolane, or 2-(4-chlorophenyl-1,3,2-dioxaborolane.

4. The light-emitting composition as claimed in claim 1, wherein an average emission life of the compound is from about 0.07 to about 2.5 seconds.

5. A method of marking a biomaterial, the method comprising marking the biomaterial with the light-emitting composition as claimed in claim 1.

6. A method of manufacturing a light-emitting printing matter, the method comprising printing an image on a base material using an ink that includes the light-emitting composition as claimed in claim 1.

7. The method of manufacturing a light-emitting printing matter as claimed in claim 6, wherein the image is a bar code.

8. An organic electroluminescent device, comprising:
an anode,
a cathode, and
an organic compound layer provided therebetween,
wherein the organic compound layer includes the light-emitting composition as claimed in claim 1.

9. A display including the organic electroluminescent device as claimed in claim 8.

10. An oxygen sensor, comprising:
a support,
an oxygen permeable layer, and
an emission layer provided therebetween,
wherein the emission layer includes the light-emitting composition as claimed in claim 1.

11. A method of measuring oxygen concentration, the method comprising:
contacting the oxygen sensor as claimed in claim 10 with a sample,
irradiating light to the oxygen sensor,
measuring emission life of phosphorescence generated from the emission layer by the irradiation of light, and
obtaining the oxygen concentration in the sample from the emission life.

12. A solar cell, comprising:
a metal oxide semiconductor electrode on a conductive support, a sensitizing dye being adsorbed on the metal oxide semiconductor electrode,
a counter electrode thereof, and
an oxidation reduction electrolyte,
wherein the sensitizing dye is the light-emitting composition as claimed in claim 1.

13. A light-emitting method using the light-emitting composition as claimed in claim 1, the method comprising irradiating light to the light-emitting composition.
